(19) United States
(12) Patent Application Publication
(10) Pub. No.: US 2016/0111640 A1
(43) Pub. Date: Apr. 21, 2016

(54) RESISTIVE RANDOM ACCESS MEMORY

(71) Applicant: NATIONAL SUN YAT-SEN UNIVERSITY, Kaohsiung (TW)

(72) Inventors: Ting-Chang Chang, Kaohsiung (TW); Kuan-Chang Chang, Kaohsiung (TW); Tsung-Ming Tsai, Kaohsiung (TW); Tian-Jian Chu, Kaohsiung (TW); Chih-Hung Pan, Kaohsiung (TW)

(21) Appl. No.: 14/559,112

(22) Filed: Dec. 3, 2014

(30) Foreign Application Priority Data
Oct. 15, 2014 (TW) 103135722

(51) Int. Cl. H01L 45/00

(52) U.S. Cl. CPC H01L 45/1253; H01L 45/1233; H01L 45/146

(57) ABSTRACT

A resistive random access memory including two electrode layers and a multi-resistance layer mounted between the two electrode layers. The multi-resistance layer consists essentially of insulating material with oxygen and lithium ions. The number of resistance states of a memory element can be increased by the resistive random access memory to increase the integration density of a memory module having a plurality of memory elements.

### BACKGROUND OF THE INVENTION

1. Field of the Invention

The present invention relates to a resistive random access memory and, more particularly, to a resistive random access memory capable of forming multi-resistance states.

2. Description of the Related Art

Memories have been widely used in various electronic products. Due to the increasing need of data storage, the demands of the capacities and performances of the memories become higher and higher. Among various memory elements, resistive random access memories (RRAMs) have an extremely low operating voltage, an extremely high read/write speed, and highly miniaturization of the element size and, thus, may replace the conventional flash memories and dynamic random access memories (DRAMs) as the main stream of memory elements of the next generation.

FIG. 1a is a diagrammatic view illustrating resistance switching of a conventional resistive random access memory 9. The conventional resistive random access memory 9 includes two metal layers 91 and a resistive switching layer 92. The resistive switching layer 92 is formed by silicon oxide and is located between the two metal layers 91 to form a metal/insulator/metal (MIM) structure. One of the metal layers 91 can be connected to an external DC power source. An electric field can be created to drive oxygen ions 922. Metal filaments 921 in the resistive switching layer 92 and oxygen ions 922 undergo oxidation/reduction reaction to switch the resistive switching layer 92 into a low resistance state (LRS) or a high resistance state (HRS) for storing the digital logic state (such as 0 or 1).

FIG. 1b is a diagram of a current-voltage curve of the conventional resistive random access memory 9. Since the resistive switching layer 92 of the conventional resistive random access memory 9 is made of silicon oxide that can only provide the oxygen ions 922 to react with the metal filaments, the resistance states represented by the current-voltage curve concentrate in the low resistance state and the high resistance state. The high resistance state cannot have a large area of randomly distribution such that a single memory element can only be used to store two resistance states (the logic states); namely, only one bit (see FIG. 1c or FIG. 1d). Thus, when used to produce a memory module, the desired number of the memory elements must be equal to the bit of stored data, leading to difficulties in increasing the integration density of the memory module and in reducing the volume. However, the integration density of the memory module must be increased to meet the practical needs in view of the increase in the data capacity and the trend of compactness of operating devices.

Thus, improvement to the conventional techniques is required for enhancing the utility.

### SUMMARY OF THE INVENTION

An objective of the present invention is to provide a resistive random access memory with more resistance states for a memory unit for storage purposes to thereby increase the integration density of the memory module.

The present invention fulfills the above objective by providing a resistive random access memory including two electrode layers and a multi-resistance layer mounted between the two electrode layers. The multi-resistance layer consists essentially of insulating material with oxygen and lithium ions.

The mole percent of lithium ions can be 0.5-10%.

The insulating material with oxygen can include silicon oxide or hafnium oxide.

The two electrode layers can be made of platinum or titanium nitride.

The multi-resistance layer can have a thickness of 2-20 nm.

The lithium ions and the oxygen ions in the multi-resistance layer of the resistive random access memory can be used to change the resistance states of the multi-resistance layer by an oxidation/reduction reaction. The mobility of the lithium ions can be used to modify the characteristics of the multi-resistance layer, such that the high resistance states present a large area of randomly distribution serving as a basis for distinguishing different resistances. Thus, the number of resistance states of a single memory element for storage can be increased to increase the integration density of the memory module.

The present invention will become clearer in light of the following detailed description of illustrative embodiments of this invention described in connection with the drawings.

### BRIEF DESCRIPTION OF THE DRAWINGS

The illustrative embodiments may best be described by reference to the accompanying drawings where:

FIG. 1a is a diagrammatic view illustrating resistance switching of a conventional resistive random access memory.

FIG. 1b is a diagram of a current-voltage curve of the conventional resistive random access memory.

FIG. 1c is a diagram of an enlarged current-negative voltage curve of the conventional resistive random access memory.

FIG. 1d is a diagram of an enlarged current-positive voltage curve of the conventional resistive random access memory.

FIG. 2 is a perspective view of a resistive random access memory of an embodiment according to the present invention.

FIG. 3a is a diagrammatic view illustrating resistance switching of the resistive random access memory of the embodiment according to the present invention.

FIG. 3b is a diagram of a current-voltage curve of the resistive random access memory of the embodiment according to the present invention.

FIG. 4a is a diagram of a current-voltage curve of the resistive random access memory of the embodiment according to the present invention in which the working signal has a positive value.

FIG. 4b is a diagram of a current-voltage curve of the resistive random access memory of the embodiment according to the present invention in which the working signal has a negative value.

FIG. 5a is a diagram of a current-voltage curve of the resistive random access memory of the embodiment according to the present invention using four-resistance states.

FIG. 5b is a diagram illustrating durability tests of the current-voltage curve of the resistive random access memory of the embodiment according to the present invention using four-resistance states.

FIG. 6a is a diagram illustrating a resistance-pulse number curve of the resistive random access memory of the embodiment according to the present invention.

FIG. 6b is an enlarged diagram illustrating resistances of a single period of FIG. 6a.

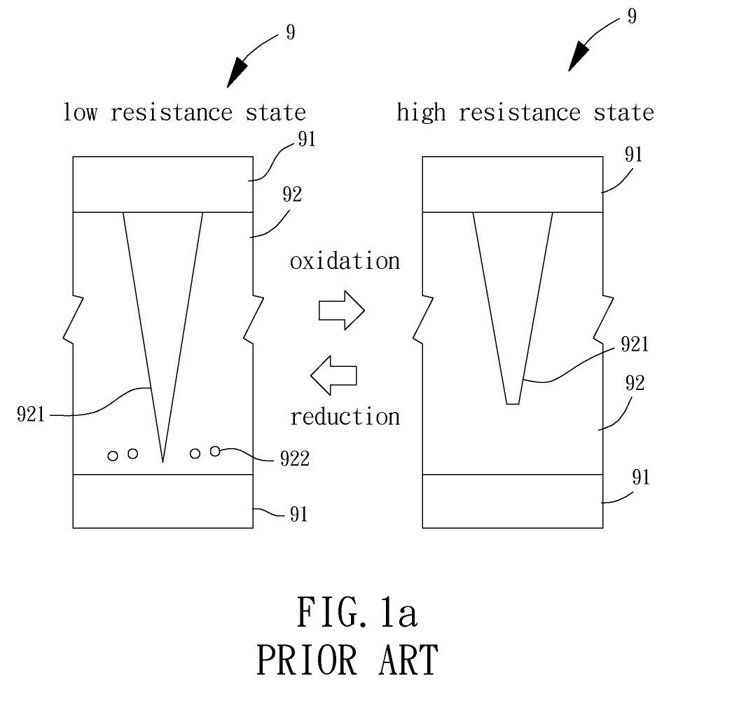

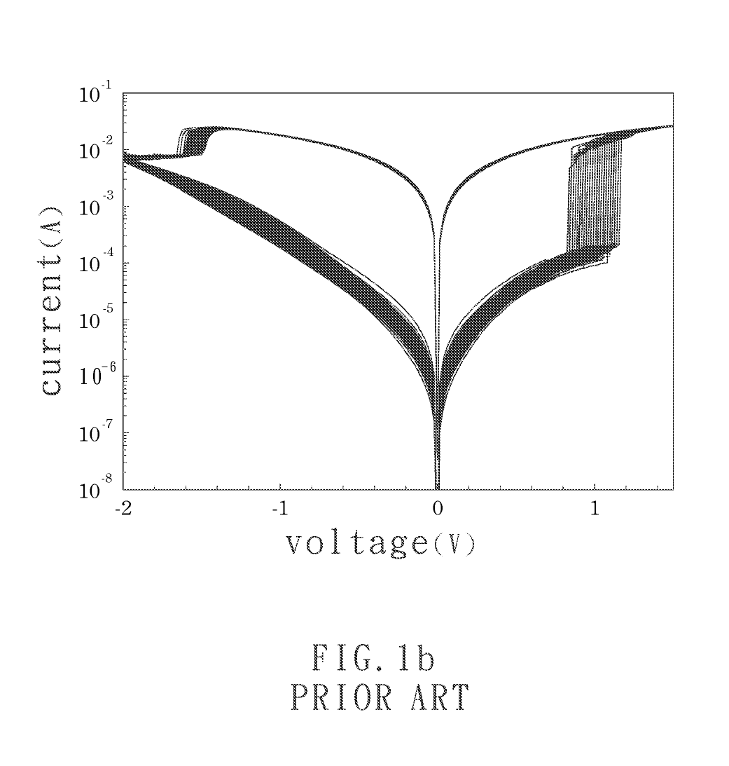

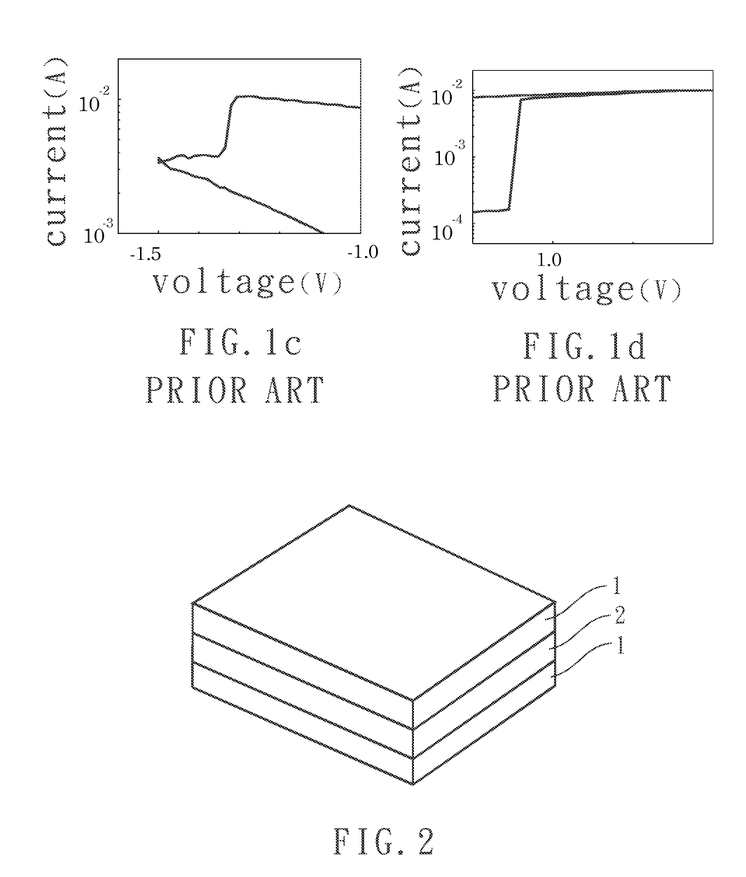

### DETAILED DESCRIPTION OF THE INVENTION

FIG. 2 is a perspective view of a resistive random access memory of an embodiment according to the present invention. The resistive random access memory includes two electrode layers 1 and a multi-resistance layer 2. The electrode layers 1 are made of a conductive material and are used to apply a working signal to the resistive random access memory. The multi-resistance layer 2 is mounted between the two electrode layers 1. The multi-resistance layer 2 consists essentially of insulating material with oxygen and lithium ions and is used to generate multi-resistance states, such as a first low resistance state (first LRS), a second low resistance state (second LRS), a first high resistance state (first HRS), and a second high resistance state (second HRS). However, the present invention is not limited to this example. The resistive random access memory can be formed by, but not limited to, a conventional sputtering procedure for forming semiconductors to reduce the manufacturing costs.

In this embodiment, the two electrode layers 1 can be made of a conductive material, such as platinum or titanium nitride (TiN), to increase the conduction effect. The insulating material with oxygen can be silicon oxide (SᵢOₓ, x=1 or 2) or hafnium oxide (H_{f}Oₓ, x=1 or 2) to change the resistance state of the multi-resistance layer 2 by an oxidation/reduction action, which can be appreciated by one having ordinary skill in the art. A mole percent of the lithium ions can be 0.5-10%. As an example, the mole percent of lithium ions in the multi-resistance layer 2 is 1%, with the remainder being the insulating material with oxygen. In an alternative example, the remainder is the insulating material with oxygen and a metal material, such as zirconium, titanium, or hafnium. The present invention is not limited to these examples. The thickness of the multi-resistance layer 2 can be 2-20 nm

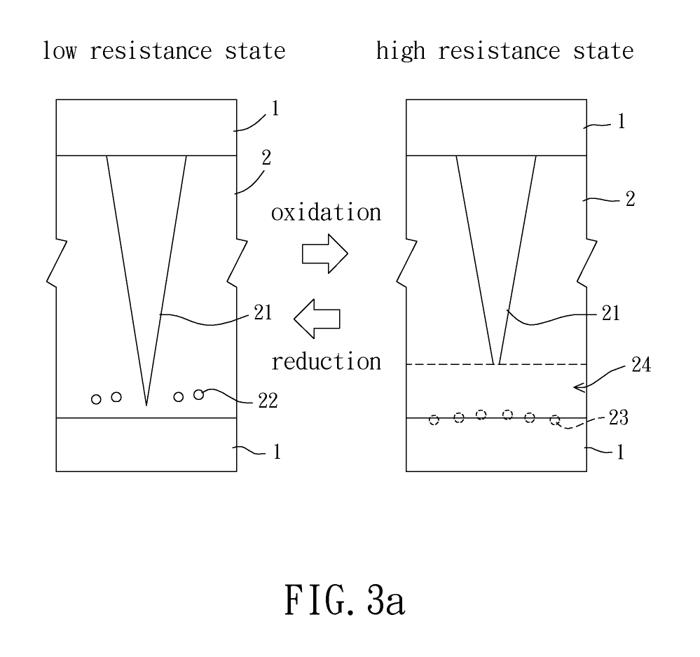

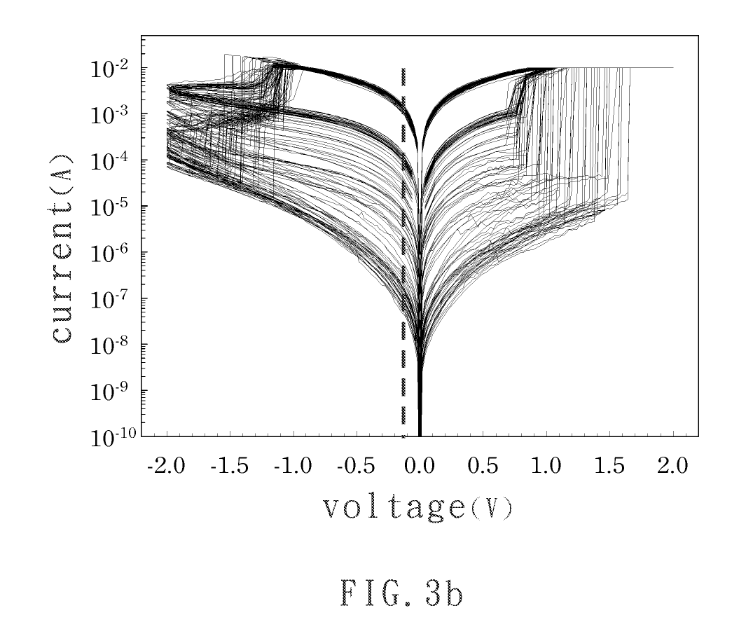

Still referring to FIG. 2, in use of the resistive random access memory of the embodiment according to the present invention, a working signal is applied between the two electrode layers 1. The working signal can be a pulse width modulation (PWM) signal. The polarity (positive or negative), amplitude, working period, and frequency (the number of pluses per unit of time) of the pulse width modulation signal can be adjusted. After an initial forming process, an electric field can be used to drive the oxygen ions and the lithium ions. As can be seen from FIG. 3a, the metal filaments 21 of the multi-resistance layer 2 can react with the oxygen ions 22 to undergo an oxidation/reduction reaction, switching the multi-resistance layer 2 into a high resistance state or a low resistance state while presenting bipolar switching characteristics.

Still referring to FIG. 3a, since the multi-resistance layer 2 contains oxygen ions 22 and lithium ions 23, the oxygen ions 22 can undergo an oxidation/reduction reaction to change the resistance state of the multi-resistance layer 2. The insulating material with oxygen 24 (such as silicon oxide) can be laminated between the metal filaments 21 and the lower electrode layer 1 (see the drawing sheet). The lithium ions 23 can be distributed between the metal filaments 21 and the lower electrode layer 1 (see the drawing sheet). Since the lithium ions 23 are mobile, the lithium ions 23 can be used to modify the characteristics of the multi-resistance layer 2. Furthermore, the mobility of the lithium ions 23 and the oxidation ability of the oxygen ions 22 permit both of the oxygen ions 22 and the lithium ions 23 to participate in the chemical reaction process, causing a slight change in the oxidation degree of the metal filaments 21 of the multi-resistance layer 2.

FIG. 3b is a diagram of a current-voltage curve of the resistive random access memory of the embodiment according to the present invention. When the frequency of the pulse width modulation signal changes, a different number of pulses can be generated in the multi-resistance layer 2, such that the high resistance states (having lower currents) in the multi-resistance layer 2 present a large area of randomly distribution, forming multi-resistance states that can be used as a basis for storage of many logic states, such as four-resistance states for storage of 2 bits (00, 01, 10, and 11). In comparison with the conventional resistive random access memory merely permitting storage of 1 bit, the resistive random access memory of the embodiment according to the present invention increases the storage amount per unit of the resistive random access memory.

Thus, the resistive random access memory of the embodiment according to the present invention can clearly define many distinguishable resistance states by properly adjusting the amplitude (such as −0.1V) and the frequency (such as 950-1200 Hz) of the pulse width modulation signal, such that the resistance states capable of storing logic values of a single memory element can be increased to reduce the desired number of the memory elements of a memory module, reducing the volume of the memory module.

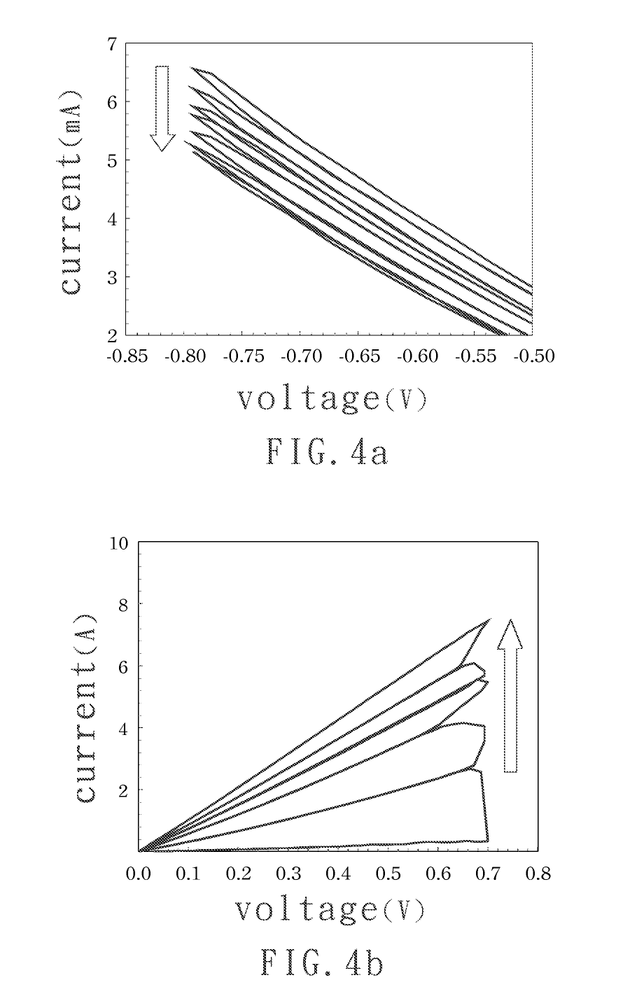

FIG. 4a and FIG. 4b are diagrams of current-voltage curves of the resistive random access memory of the embodiment according to the present invention in which the working signal have a positive value and a negative value, respectively. Since the resistive random access memory of the embodiment can present the bipolar switching characteristics, when the amplitudes of the working signal are respectively a positive value and a negative value, minor adjustment of the values of the voltage and the current of the resistive random access memory of the embodiment according to the present invention can be proceeded to generate current-voltage curves with distinguishable resistance states. Thus, when the resistive random access memory of the embodiment according to the present invention is used as a memory element of a memory module, the amount of stored bit of each memory element can be increased, such that the data storage amount of the whole memory module of the same volume is increased, increasing the integration density of the memory module. The present invention will be further described by using the four-resistance states as a non-restrictive example.

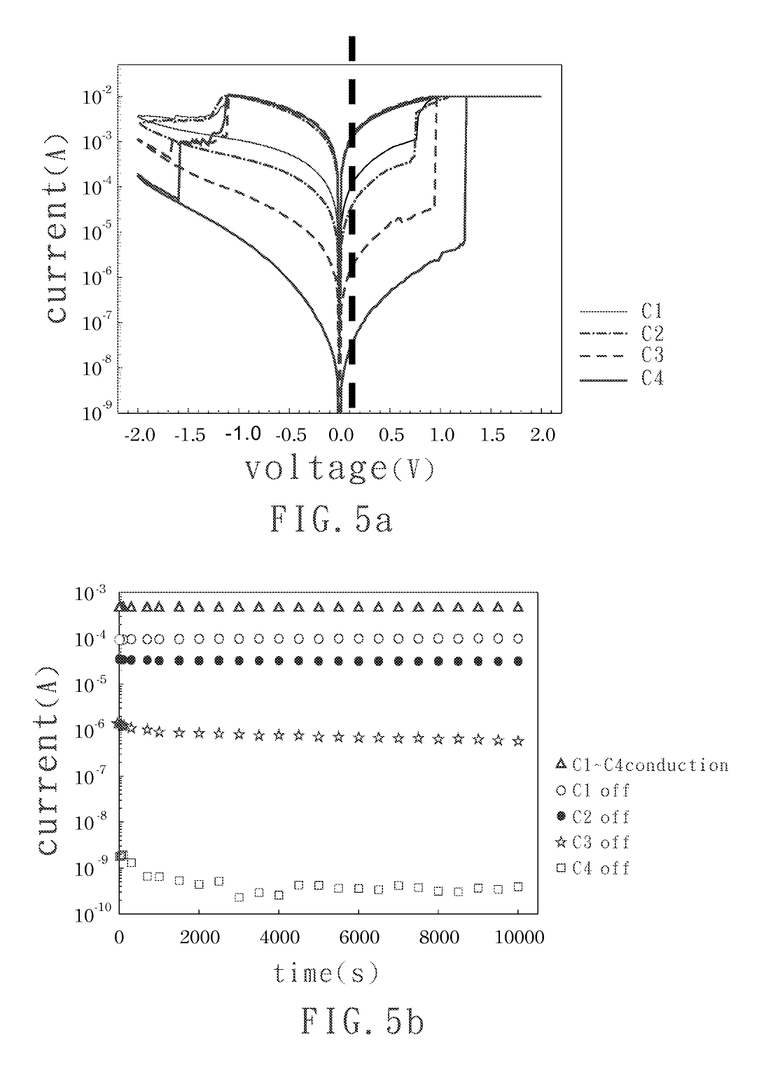

FIG. 5a is a diagram of a current-voltage curve of the resistive random access memory of the embodiment according to the present invention using four-resistance states. When the amplitudes of the working signal between the two electrode layers 1 are respectively a positive value and a negative value, four resistance state curves C1-C4 are obtained. The low resistance states (which have larger currents and which can be considered as conductive states) of the resistance state curves C1-C4 almost completely overlap with each other. The high resistance states (which have smaller currents and which can be considered as off states) of the resistance state curves C1-C4 distribute uniformly and are clearly distinguishable. Thus, the resistive random access memory of the embodiment according to the present invention can store four logic states of 2 bits by using the resistance state curves C1-C4 while reducing the possibility of wrong judgment of data.

FIG. 5b is a diagram illustrating durability tests of the current-voltage curve of the resistive random access memory of the embodiment according to the present invention using four-resistance states. During the durability tests of the resistive random access memory of the embodiment according to the present invention, the off states and the conductive states of the resistance state curves C1-C4 of FIG. 5a could be read many times in 10,000 seconds. As can be seen from FIG. 5b, after many times of reading the low resistance states of the resistance state curves C1-C4, the current values (which can be converted into resistance values) were stable, and the current values remained in clearly distinguishable states. Thus, the resistive random access memory of the embodiment according to the present invention has good working stability and is suitable for a data storage device that generally operates for a long period of time, such as a cloud server.

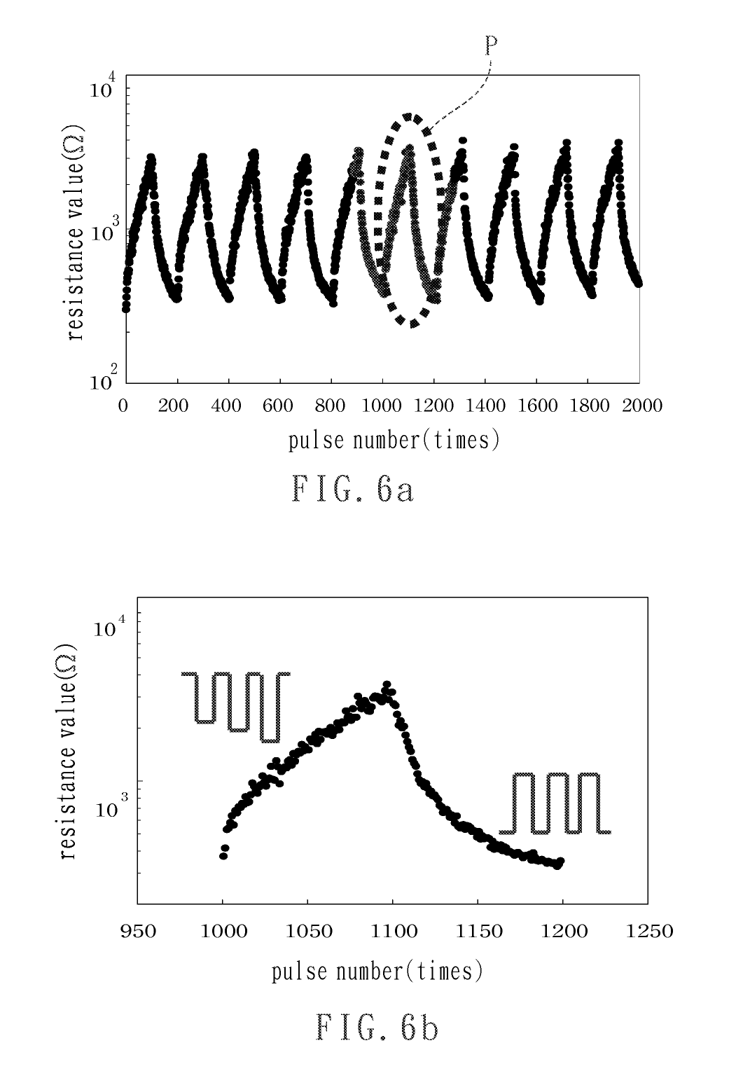

FIG. 6a is a diagram illustrating a resistance-pulse number curve of the resistive random access memory of the embodiment according to the present invention. If the amplitude of the working signal is fixed at 0.1V and if the pulse number per unit of time of the working signal is gradually increased from 0 to 2,000, the resistance values of the multi-resistance layer 2 of the resistive random access memory of the embodiment according to the present invention presents a stable periodic change. When the resistances of a single period P are enlarged (see FIG. 6b), the resistance values of the low resistance states adjusted by using the pulse numbers of the working signal in the resistive random access memory of the embodiment according to the present invention can be used as a basis for data storage/retrieval of the multi-resistance states, providing an easy-to-operate effect.

In view of the foregoing, the main features of the resistive random access memory of the embodiment according to the present invention are that the resistive random access memory includes two electrode layers 1 and a multi-resistance layer 2 mounted between the two electrode layers 1. The multi-resistance layer 2 consists essentially of insulating material with oxygen and lithium ions. The lithium ions 23 can be used to modify the characteristics of the multi-resistance layer 2. Furthermore, the mobility of the lithium ions 23 and the oxidation ability of the oxygen ions 22 permit both of the oxygen ions 22 and the lithium ions 23 to participate in the chemical reaction process, forming the multi-resistance states in the multi-resistance layer 2. A proper change in the number of pulses can serve as a basis for storage of many logic states. Thus, the resistive random access memory of the embodiment according to the present invention can reduce the desired number of the memory elements of the memory module and, thus, reduce the volume of the memory module, such that the data storage amount of the whole memory module of the same volume is increased to increase the integration density of the memory module. The disadvantages of difficulties in increasing the integration density and in reducing the volume of the conventional resistive random access memory are, thus, mitigated by the resistive random access memory according to the present invention

In addition to the advantages of increasing the integration density of the resistive random access memory and reducing the volume of the resistive random access memory, conventional semiconductor manufacturing processes can be used to manufacture the resistive random access memory according to the present invention. Furthermore, the characteristics of the pulse width modulation signals can be used to store/retrieve data. Furthermore, the resistive random access memory according to the present invention is suitable for data storage devices that have to operate for a long period of time. Namely, the resistive random access memory according to the present invention achieves the effects of low manufacturing costs, good working stability, and easy operation.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A resistive random access memory comprising:
two electrode layers; and
a multi-resistance layer mounted between the two electrode layers, with the multi-resistance layer consisting essentially of insulating material with oxygen and lithium ions.

2. The resistive random access memory as claimed in claim 1, wherein a mole percent of lithium ions is 0.5-10%.

3. The resistive random access memory as claimed in claim 1, wherein the insulating material with oxygen includes silicon oxide or hafnium oxide.

4. The resistive random access memory as claimed in claim 1, wherein the two electrode layers are made of platinum or titanium nitride.

5. The resistive random access memory as claimed in claim 1, wherein the multi-resistance layer has a thickness of 2-20 nm.
